(19) United States
(12) Patent Application Publication
(10) Pub. No.: US 2018/0166356 A1
(43) Pub. Date: Jun. 14, 2018

(54) FAN-OUT CIRCUIT PACKAGING WITH INTEGRATED LID

(71) Applicant: GLOBALFOUNDRIES INC., Grand Cayman (KY)

(72) Inventors: Shahid A. Butt, Ossining, NY (US); Koushik Ramachandran, Wappingers Falls, NY (US); Eric D. Perfecto, Poughkeepsie, NY (US)

(21) Appl. No.: 15/377,496

(22) Filed: Dec. 13, 2016

(51) Int. Cl. H01L 23/367; H01L 23/373; H01L 23/498; H01L 21/48; H01L 21/78; H01L 23/00

(52) U.S. Cl. CPC H01L 23/3675; H01L 23/3736; H01L 23/49822; H01L 23/49838; H01L 23/49816; H01L 2224/16165; H01L 21/4882; H01L 21/4853; H01L 21/4857; H01L 21/78; H01L 24/16; H01L 23/49894

(57) ABSTRACT

Various embodiments include integrated circuit (IC) package structures. In some cases, an IC package includes: a carrier having a recess; a plurality of IC chips coupled with the carrier inside the recess, the plurality of IC chips each including a plurality of connectors; a thermally conductive material between the plurality of IC chips and the carrier within the recess, the thermally conductive material coupling the plurality of IC chips with the carrier; a dielectric layer contacting the plurality of IC chips and the carrier; a redistribution layer (RDL) contacting the dielectric layer and the plurality of connectors, the RDL including a plurality of fan-out vias extending from the plurality of connectors and at least one connector coupling adjacent IC chips in the plurality of IC chips; and a set of solder balls contacting the RDL and connected with the plurality of fan-out vias.

### BACKGROUND

The subject matter disclosed herein relates to integrated circuit devices. More particularly, the subject matter relates to integrated circuit packaging.

As integrated circuit (IC) technologies have advanced, the size of transistors has correspondingly decreased. The packaging for these devices has also become increasingly complex, especially given the amount of heat generated by ICs in high performance applications.

### SUMMARY

Various embodiments include integrated circuit (IC) package structures. A first aspect of the disclosure, an IC package can include: a carrier having a recess; a plurality of integrated circuit chips coupled with the carrier inside the recess, the plurality of integrated circuit chips each including a plurality of connectors; a thermally conductive material between the plurality of integrated circuit chips and the carrier within the recess, the thermally conductive material coupling the plurality of integrated circuit chips with the carrier; a dielectric layer contacting the plurality of integrated circuit chips and the carrier; a redistribution layer (RDL) contacting the dielectric layer and the plurality of connectors, the RDL including a plurality of fan-out vias extending from the plurality of connectors and at least one connector coupling adjacent integrated circuit chips in the plurality of integrated circuit chips; and a set of solder balls contacting the RDL and connected with the plurality of fan-out vias.

A second aspect of the disclosure includes an integrated circuit (IC) package having: a carrier having a recess, wherein the carrier includes copper or aluminum; a plurality of integrated circuit chips coupled with the carrier inside the recess, the plurality of integrated circuit chips each including a plurality of connectors; a thermally conductive material between the plurality of integrated circuit chips and the carrier within the recess, the thermally conductive material coupling the plurality of integrated circuit chips with the carrier; a dielectric layer contacting the plurality of integrated circuit chips and the carrier, the dielectric layer having a thickness measured from an upper surface of the carrier, the dielectric layer thickness being approximately equal to a height of each of the plurality of connectors as measured from an upper surface of a corresponding one of the plurality of integrated circuit chips; a redistribution layer (RDL) contacting the dielectric layer and the plurality of connectors, the RDL including a plurality of fan-out vias extending from the plurality of connectors and at least one connector coupling adjacent integrated circuit chips in the plurality of integrated circuit chips; and a set of solder balls contacting the RDL and connected with the fan-out vias.

### BRIEF DESCRIPTION OF THE DRAWINGS

These and other features of this invention will be more readily understood from the following detailed description of the various aspects of the invention taken in conjunction with the accompanying drawings that depict various embodiments of the invention, in which:

FIG. 1 shows a schematic cross-sectional view of an integrated circuit (IC) package according to various embodiments of the disclosure.

FIG. 2 shows a schematic cross-sectional view of an integrated circuit (IC) package according to additional embodiments of the disclosure.

FIG. 3 shows a schematic cross-sectional view of an integrated circuit (IC) package according to additional embodiments of the disclosure.

FIG. 4 shows a schematic cross-sectional view of an integrated circuit (IC) package according to further embodiments of the disclosure.

FIG. 5 shows a schematic cross-sectional view of a structure undergoing an additional process in a method according to various embodiments of the disclosure.

FIG. 6 shows a schematic cross-sectional view of a structure undergoing an additional process in a method according to various embodiments of the disclosure.

FIG. 7 shows a schematic cross-sectional view of a structure undergoing an additional process in a method according to various embodiments of the disclosure.

FIG. 8 shows a schematic cross-sectional view of a structure undergoing an additional process in a method according to various embodiments of the disclosure.

FIG. 9 shows a schematic cross-sectional view of a structure undergoing an additional process in a method according to various embodiments of the disclosure.

FIG. 10 shows a schematic cross-sectional view of a structure undergoing an additional process in a method according to various embodiments of the disclosure.

FIG. 11 shows a schematic cross-sectional view of a structure undergoing an additional process in an additional method according to various embodiments of the disclosure.

FIG. 12 shows a schematic cross-sectional view of a structure undergoing an additional process in an additional method according to various embodiments of the disclosure.

FIG. 13 shows a schematic cross-sectional view of a structure undergoing an additional process in an additional method according to various embodiments of the disclosure.

FIG. 14 shows a schematic cross-sectional view of a structure undergoing an additional process in an additional method according to various embodiments of the disclosure.

FIG. 15 shows a schematic cross-sectional view of a structure undergoing an additional process in an additional method according to various embodiments of the disclosure.

FIG. 16 shows a schematic cross-sectional view of a structure undergoing an additional process in an additional method according to various embodiments of the disclosure.

FIG. 17 shows a schematic cross-sectional view of an integrated circuit (IC) package according to further embodiments of the disclosure.

FIG. 18 shows a schematic cross-sectional view of an integrated circuit (IC) package according to additional embodiments of the disclosure.

It is noted that the drawings of the invention are not necessarily to scale. The drawings are intended to depict only typical aspects of the invention, and therefore should not be considered as limiting the scope of the invention. In the drawings, like numbering represents like elements between the drawings.

### DETAILED DESCRIPTION

As noted, the subject matter disclosed herein relates to integrated circuits (ICs). More particularly, the subject matter relates to wafer-level fan-out (WLFO) and/or panel-level fan out packages for ICs.

In the following description, reference is made to the accompanying drawings that form a part thereof, and in which specific embodiments are shown by way of illustration. These embodiments are described in sufficient detail to enable those skilled in the art to practice the present teachings and it is to be understood that other embodiments may be utilized and that changes may be made without departing from the scope of the present teachings. The following description is, therefore, merely illustrative.

As described herein, “depositing” may include any now known or later developed techniques appropriate for the material to be deposited including but are not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metalorganic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), molecular layer deposition, evaporation.

As discussed herein, designing IC packaging capable of dissipating heat from those circuits within the ever-smaller size constraints has become particularly challenging. One conventional packaging approach, called wafer-level fan-out (WLFO) packaging, implements a fanned-out connection between an IC die and corresponding solder connectors (e.g., solder bumps). While WLFO packaging has been useful in low-power circuits and those with limited input/output (I/O) capabilities, these conventional WLFO packages struggle to adequately dissipate heat in higher-power circuits and those with greater I/O capabilities.

In contrast to conventional structures, various embodiments of the disclosure include a wafer-level fan-out (WLFO) or panel level fan-out package with an integral thermal lid for dissipating thermal energy from the die and other interconnect structures. The various structures described herein are formed by integrating the thermal lid prior to forming interconnects and solder bumps. These devices can be formed with minimal additional steps to the traditional process flow, thereby maintaining low costs. The various aspects of the disclosure may be applied to panels of varying size, e.g., 300 millimeter (mm) diameter wafers, 400×500 mm panels, etc.

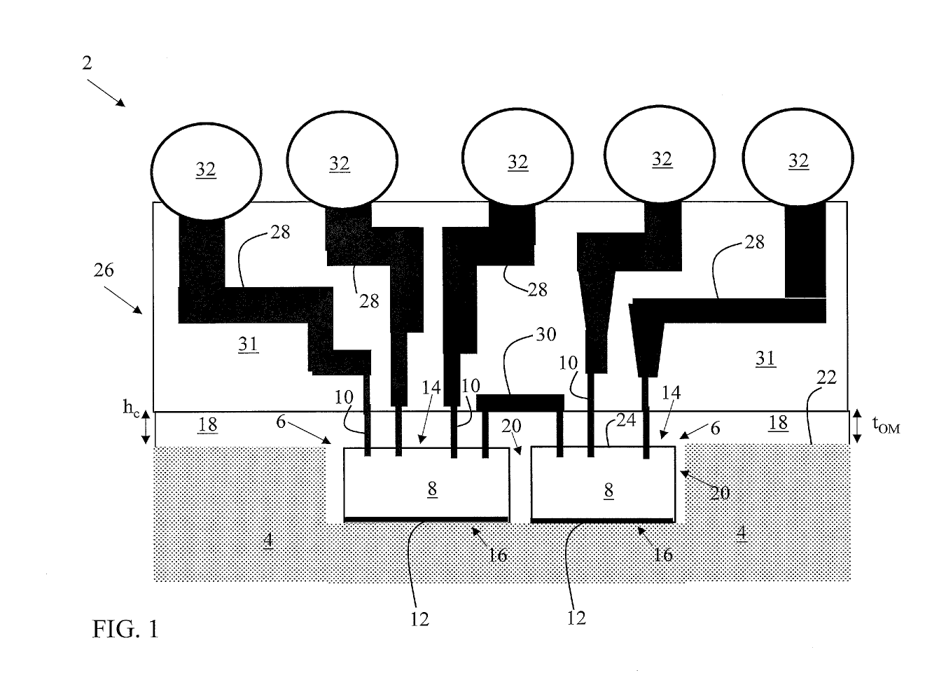

FIG. 1 shows a schematic depiction of an IC package 2 according to various embodiments of the disclosure. In various embodiments, IC package 2 is shown in a particular orientation (with carrier 4 at bottom), however, it is understood that IC package 2 can be oriented in any number of manners, and reference to terms such as above, below, upper, lower, etc. is merely for facilitating explanation of the FIGURES, and not limiting of the disclosure. As shown, IC package 2 can include a carrier 4 having a recess 6 therein. In various embodiments, carrier 4 is formed of a metal such as copper or aluminum. In some cases, carrier 4 is formed entirely (or substantially entirely, permitting nominal impurities) of the metal, e.g., copper (Ni plated copper), or aluminum. In other embodiments, carrier 4 is formed entirely (or substantially entirely, permitting nominal impurities) of one or more of CuW, SiC, CuSiC, AlSiC, AN, diamond, graphite, silicon or composite materials. IC package 2 can further include a plurality of integrated circuit (IC) chips 8 coupled with carrier 4 inside recess 6. In some cases, IC chips 8 can include memory devices, logic devices, capacitors or any other conventional IC chip that may benefit from the heat dissipating effects of IC package 2. IC chips 8 can further include a plurality of connectors 10 according to various embodiments. Connectors 10, as described herein, can provide electrical connection between IC chips 8 and other devices, and/or between IC chips 8. In various embodiments, connectors 10 include a set of copper pillars or one or more copper vias. However, it is understood that connectors 10 may include any other known connector device. IC package 2 can also include a thermally conductive material 12 between IC chips 8 and carrier 4 within recess 6. Thermally conductive material 12 can couple IC chips 8 with carrier 4, e.g., as an adhesive, and can include solder or a thermally conductive gel. Carrier 4 can further include one or more epoxies, silicones, urethanes, acrylates, etc., with thermally conductive fillers (e.g., silver, diamond, aluminum nitride, boron nitride, zinc oxide, etc.). In still further embodiments, carrier 4 can include solder, indium, thermal greases and/or thermally conductive pads. As shown in FIG. 1, connectors 10 contact a surface 14 of each chip 8 opposite thermally conductive material 12 (which contacts IC chip 8 on side 16).

In various embodiments, a dielectric layer 18 contacts the plurality of IC chips 8 and carrier 4. In some cases, dielectric layer 18 fills any gaps 20 within recess 6 between IC chips 8 and carrier 4, and between IC chips 8. In some cases, dielectric layer 18 includes an inorganic passivation material such as thermal barrier oxide (TBO) silicon oxide or silicon nitride and/or an organic material such as polyimide (PI), polybenzoxazole (PBO), benzocyclobutene (BCB), Phenolic resin, olefin or conventional epoxy molding compound. However, in some embodiments, dielectric layer 18 is completely free of epoxy. This plurality of dielectric material choices are possible because according to various embodiments of the disclosure, IC chips 8 reside within recesses 6 in panel 4, allowing dielectric layer 18 to be formed as a thinner layer than conventional dielectric materials. This thinner layer can be free of epoxy, which is a traditional dielectric material when using a thicker layer. According to various embodiments, where connectors 10 include copper vias, dielectric layer 18 has a thickness (t_{OM}) measured from an upper surface 22 of carrier 4 that is equal to a height (h_{C}) of each of the plurality of connectors 10 (e.g., copper vias) as measured from an upper surface 24 of a corresponding one of the IC chips 8. In other cases, where connectors 10 include copper pillars, height (h_{C}) of the copper pillars is equal to or greater than thickness (t_{OM}) of dielectric layer 18.

In some cases, IC package 2 can further include a redistribution layer (RDL) 26 contacting dielectric layer 18 and plurality of connectors 10. RDL 26 can include a plurality of fan-out vias 28 extending from the plurality of connectors 10 and at least one connector 30 coupling adjacent IC chips 8. RDL 26 can further include an insulator 31, such as an organic dielectric or a photosensitive material. In various embodiments, RDL 26 can include PI, PBO, BCB, epoxy or another material within which via openings can be photo-defined or ablated, e.g., using a laser. IC package 2 can also include a set of solder balls 32 contacting RDL 26 and connected with the plurality of fan-out vias 28.

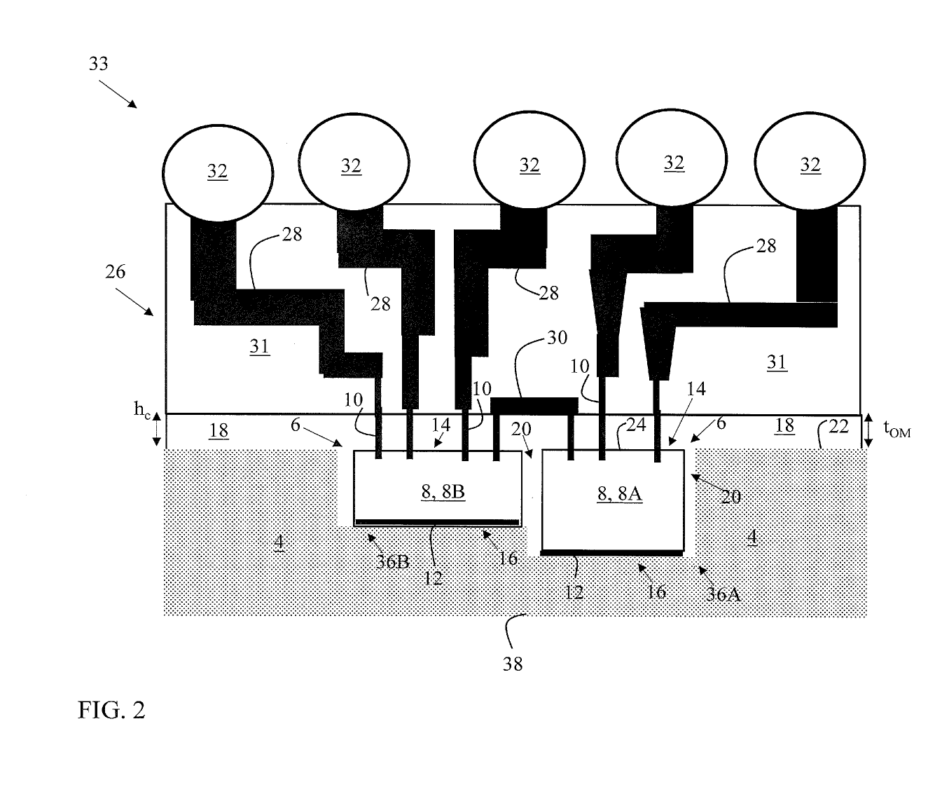

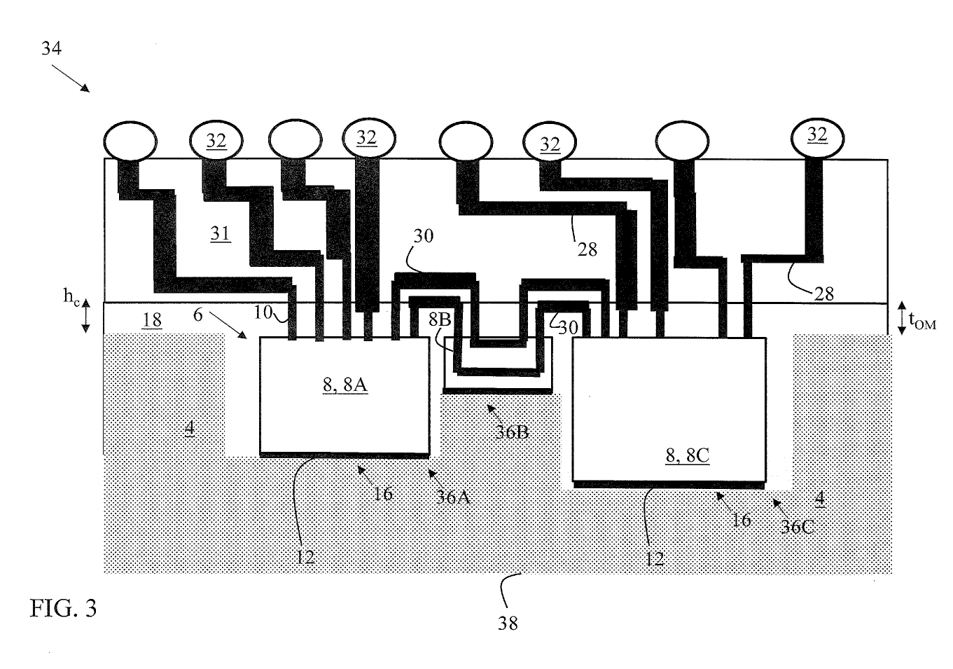

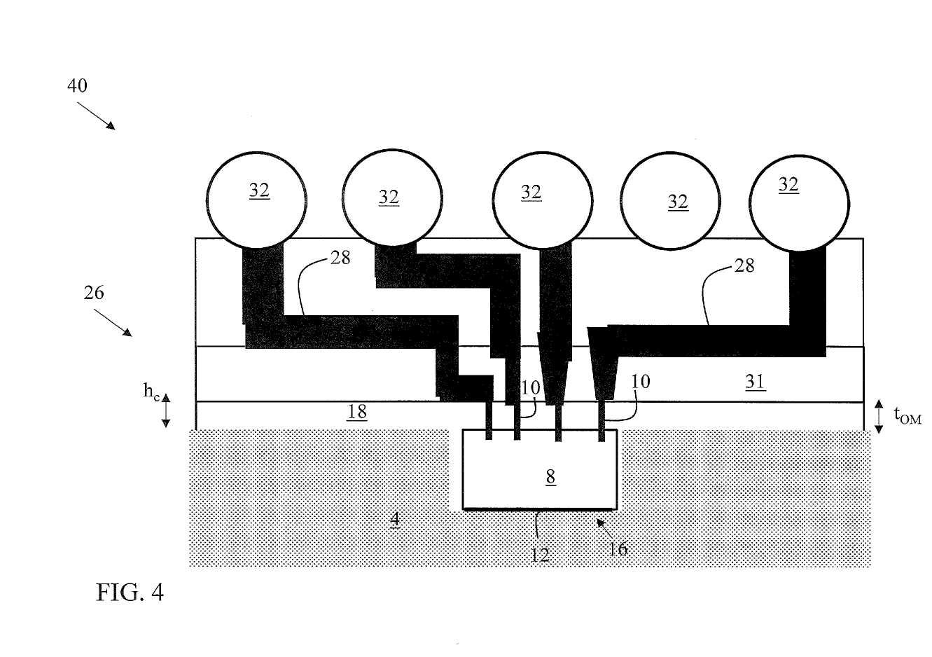

FIG. 2 shows an alternative embodiment of an IC package 33, where recess 6 includes at least two distinct levels 35A, 36B as measured from a bottom surface 38 of carrier 4. In some cases, as shown in an alternative embodiment of an IC package 33 in FIG. 2, recess 6 can include at least two distinct levels 36A, 36B as measured from a bottom surface 38 of carrier 4. In these cases, a first one of the plurality of IC chips 8A is aligned at a first one of the two distinct levels 36A and a second one of the plurality of integrated circuit chips 8B is aligned at a second one of the two distinct levels 36B. FIG. 3 shows another alternative embodiment of an IC package 34, illustrating an additional level 36C within carrier 4, including another IC chip 8C at the distinct level. In IC package 34, an intermediary (or middle) IC chip 8B may provide a high-density interconnection between adjacent IC chips 8A and 8C. FIG. 4 illustrates another embodiment of an IC package 40 which includes a recess 6 corresponding with a single IC chip 8. In this cases, as in IC package 2, IC package 33 and IC package 34, dielectric layer 18 can be completely free of epoxy, because of thickness (t_{OM}) of dielectric layer 18.

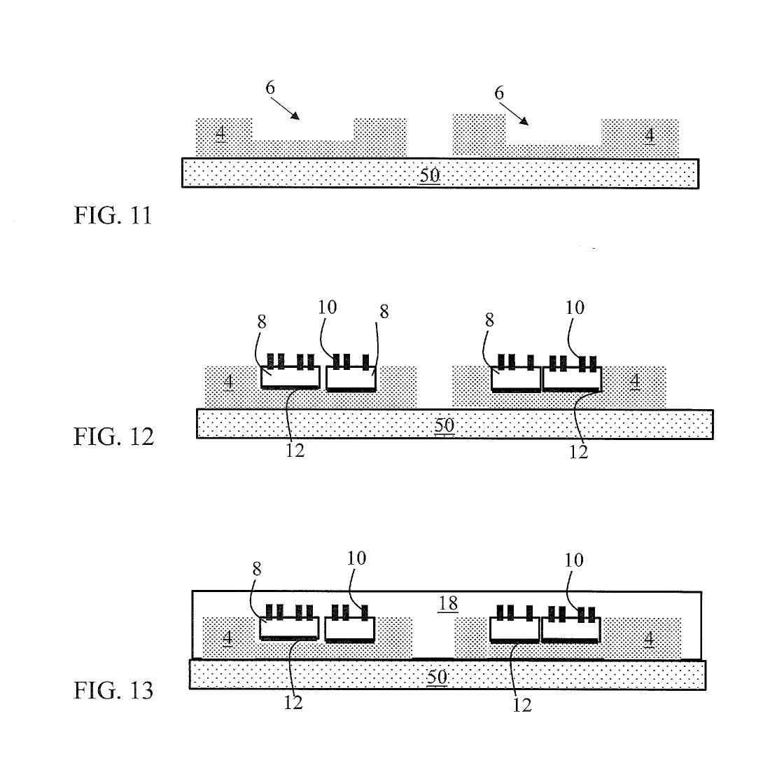

FIGS. 5-16 show schematic cross-sectional depictions of integrated circuit package structures (and precursor structures) that illustrate processes performed according to various embodiments. It is understood that the processes outlined herein may be performed in a different order than described in some embodiments. Additionally, not all of the processes outlined herein need necessarily be performed according to various embodiments. IC packages (e.g., IC packages 2, 33, 34, 40, 42) disclosed herein can be formed according to various methods. FIGS. 5-10 illustrate processes in forming IC package 2 (FIG. 1), which may be slightly modified to form IC packages 33, 34 (FIGS. 2, 3). FIGS. 11-16 illustrate processes in forming IC package 40.

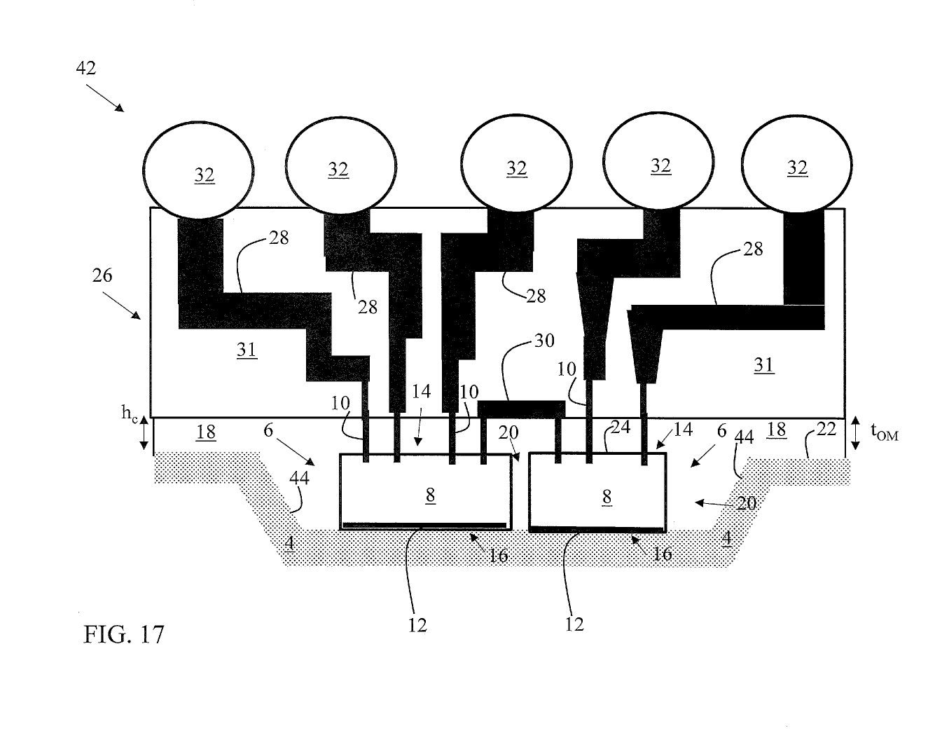

Turning to FIG. 5, a carrier 4 is shown according to various embodiments. Carrier 4 can be formed by any conventional approach known in the art, which can include depositing a metal (e.g., such as copper plated with nickel or aluminum), e.g., on a substrate, masking the metal, and etching that metal to form recesses 6. In other embodiments, carrier 4, including recesses 6 can be pre-formed, e.g., machined or stamped from a larger piece of metal. In additional embodiments, where carrier 4 is formed of graphite or a ceramic material, that carrier 4 and its recesses 6 can be formed by conventional deposition, masking and etching techniques. As discussed further herein FIG. 17 shows an IC package 42 formed on a stamped carrier 4, according to various embodiments.

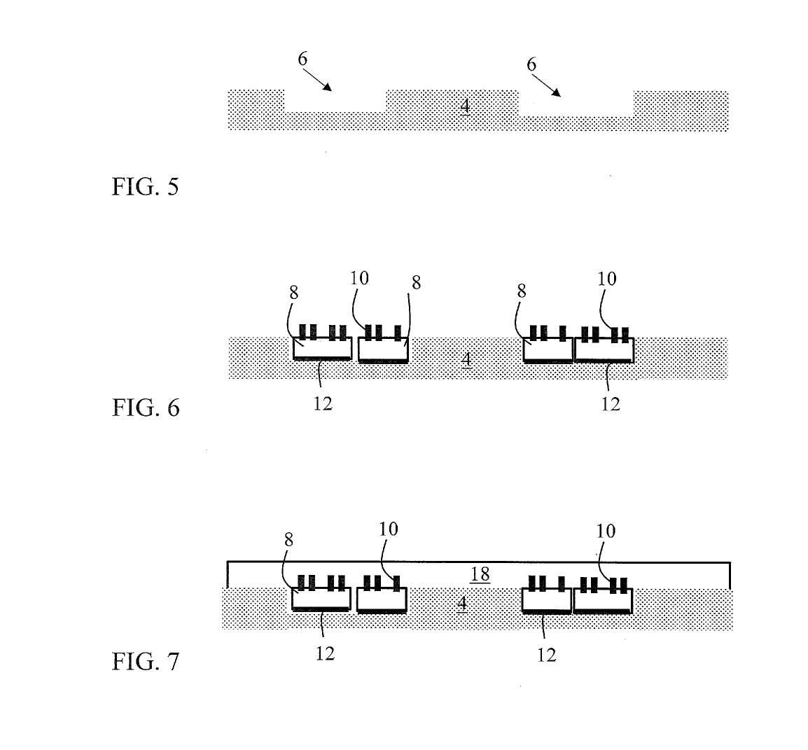

FIG. 6 illustrates a process of forming thermally conductive material 12 in recesses 6, and placing (or fabricating) IC chips 8 over thermally conductive material 12 within recesses 6. As described herein, thermally conductive material 12 can include solder or a thermally conductive gel, and in some cases, it may be selectively deposited within recesses, or deposited non-selectively using a subsequently removed mask (not shown). In some cases, IC chips 8 include connectors 10, as described herein. IC chips 8 can be pre-fabricated and placed, e.g., using a holder or conventional transporter, within recesses 6 in some embodiments. In other embodiments, IC chips 8 can be fabricated within recesses 6, according to conventional masking, etching and/or deposition methods. It is understood that according to various embodiments, connectors 10 can be formed subsequently to placing IC chips 8 over thermally conductive material 12. That is, in some cases, a photosensitive dielectric such as photosensitive polyimide (PSPI), PBO or another like material can be formed over the IC chips 8 and via openings may be photo-defined in that photosensitive dielectric. Connectors 10 may then be plated, e.g., with copper or another metal, to form connectors 10.

FIG. 7 illustrates a process of forming a dielectric layer 18, which can include inorganic dielectric material(s) such as oxide and/or an organic materials such as PI, PBO, BCB, or epoxy, as noted herein. In some embodiments, however, dielectric layer 18 is completely free of epoxy. Dielectric layer 18 may be blanket deposited over IC chips 8 and carrier 4, and may fill any gaps 20 within recesses 6 between or adjacent IC chips 8.

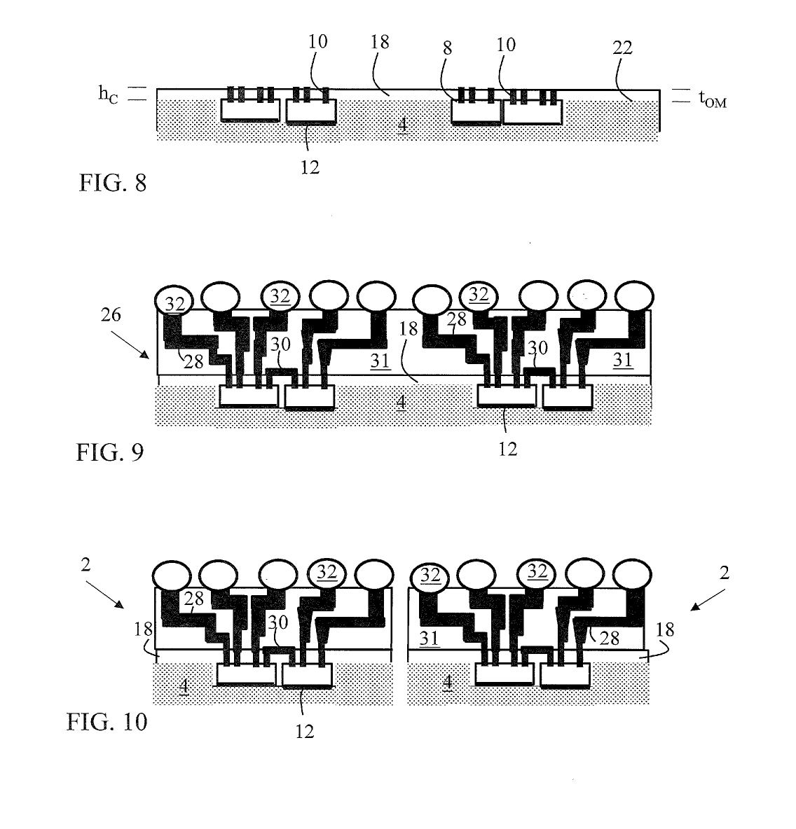

FIG. 8 illustrates a process of polishing back the dielectric layer 18, which can include any conventional polishing technique described herein or known in the art, e.g., chemical-mechanical polishing (planarization). As described herein, dielectric layer 18 can be polished back to a thickness (t_{OM}) measured from an upper surface 22 of carrier 4 that is equal to the height (h_{C}) of each of the plurality of connectors 10 as measured from upper surface 24 of a corresponding one of the IC chips 8.

FIG. 9 illustrates a process of forming RDL 26 and solder balls 32, which can include depositing insulator 31, e.g., in multiple layers, patterning and masking insulator 31, etching openings within insulator 31, and depositing a conductor to form fan-out vias 28 and connector 30 (along with removing previously placed mask). Solder balls 32 can be flowed or otherwise conventionally formed over insulator 31 and fan-out vias 28 to provide electrical connection with IC chips 8. It is understood that where RDL 26 includes a photosensitive dielectric, one or more vias 28, connector 30 or underlying connectors 10 can be formed via photo-definition or laser ablation in RDL 26, and subsequent plating, e.g., with copper or another metal, to form connectors 10.

FIG. 10 illustrates a process of dicing the precursor structure of FIG. 9 to form distinct IC packages 2 (two shown in this example), according to various embodiments. Dicing may be performed according to any conventional techniques, and can include multi-stage dicing through distinct materials, e.g., insulator 31 and carrier 4. It is understood that IC package 33 and IC package 34 (FIG. 3) can be formed in a similar manner as IC package 2 (FIG. 1, FIG. 10), except that one or more recesses 6 (FIG. 5) is formed at distinct levels 36A, 36B, 36C, etc., as measured from bottom surface 38 of carrier 4 (FIG. 2).

FIG. 11 illustrates a first process in another method, which can include forming carriers 4 over a dock 50. In various embodiments, carriers 4 formed as described with reference to FIG. 4, and are deposited over or otherwise adhered to dock 50, which may include glass, silicon or metal according to various embodiments.

FIG. 12 illustrates a similar process as shown in FIG. 6, whereby IC chips 8 are formed within recesses 6 in carriers 4. In the example process of FIG. 12, a single IC chip 8 can be formed in each recess 6 as opposed to a plurality of IC chips 8 in each recess 6 (e.g., as in FIG. 6).

FIG. 13 illustrates a similar process as shown in FIG. 7, whereby dielectric layer 18 is blanket deposited over IC chips 8 and carriers 4 (and exposed portions of dock 50). As shown in FIG. 13, a portion 52 of dielectric layer 18 is located between adjacent carriers 4 in this embodiment.

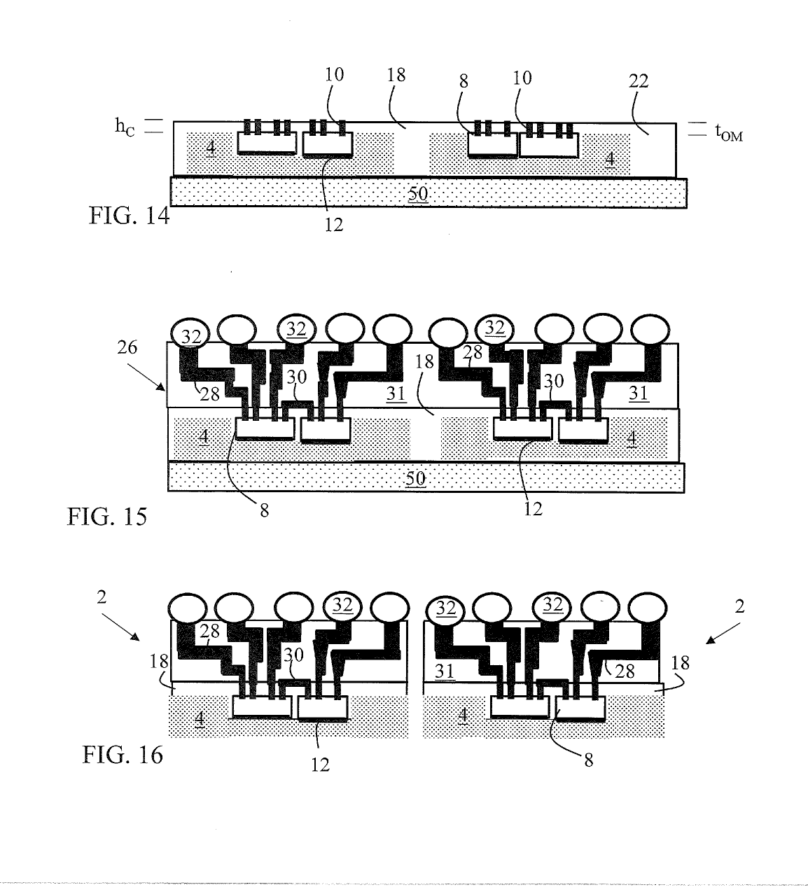

FIGS. 14 and 15 illustrate similar processes as shown in FIGS. 8 and 9, whereby dielectric layer 18 is polished back, and RDL 26 and solder balls 32 are formed over the remaining dielectric layer 18. Additionally, similarly to the processes shown in FIGS. 8 and 9, in FIGS. 14 and 15, connectors 30 may be formed to connect adjacent IC chips 8, as described herein. FIG. 16 shows the process of removing dock 50, e.g., via acid wash, bath, cleaving or any other conventional technique, to form IC package 40. Use of dock 50 in these embodiments can eliminate the need to dice through carrier(s) 4, which may eliminate dicing-related manufacturing errors relative to forming IC packages 2 and 34.

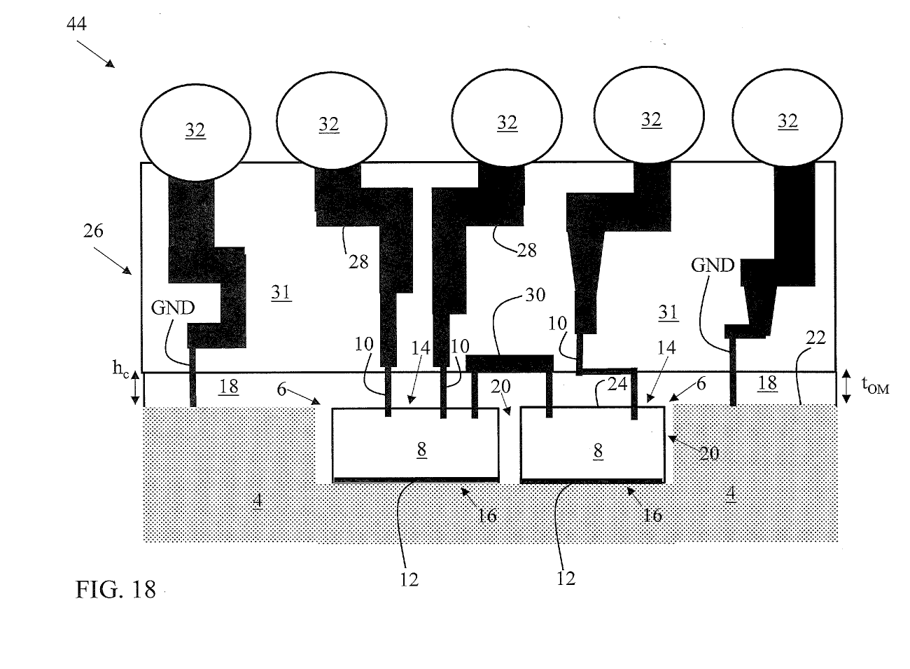

FIG. 17 shows another embodiment of an IC package 42, which is formed similarly to IC package 2 (FIG. 1), except that carrier 4 is formed of a stamped material, e.g., a stamped metal. In this case, carrier 4 may include at least one tapered surface 44 defining recess 6, which holds IC chips 8. In some cases, as shown in FIG. 17, carrier 4 can have a substantially uniform thickness across the width of IC package 42. FIG. 18 shows an example IC package 44, which may further include one or more ground contacts GND, which may connect solder balls 32 with carrier 4. In some cases, ground contacts GND may contact an upper surface of carrier 4. Ground contact(s) GND may be formed prior to, subsequently, or concurrently with processes described herein.

In any case, IC packages 2, 34, 40, 42, 44 disclosed herein can be configured to effectively dissipate heat from IC chips 8 through carriers 4 to one or more surrounding heat sinks. The integral carrier 4, along with thermally conductive material 12, allows for heat transfer from IC chips 8 through carrier 4 to an outside region (e.g., heat sink or ambient area). This configuration can be beneficial for a variety of IC applications where temperature control is a concern.

When an element or layer is referred to as being “on”, “engaged to”, “connected to” or “coupled to” another element or layer, it may be directly on, engaged, connected or coupled to the other element or layer, or intervening elements or layers may be present. In contrast, when an element is referred to as being “directly on,” “directly engaged to”, “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Spatially relative terms, such as “inner,” “outer,” “beneath”, “below”, “lower”, “above”, “upper” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. It is further understood that the terms “front” and “back” are not intended to be limiting and are intended to be interchangeable where appropriate.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. An integrated circuit (IC) package comprising:
a carrier having a recess;
a plurality of integrated circuit chips coupled with the carrier inside the recess, the plurality of integrated circuit chips each including a plurality of connectors;
a thermally conductive material between the plurality of integrated circuit chips and the carrier within the recess, the thermally conductive material coupling the plurality of integrated circuit chips with the carrier;
a dielectric layer contacting the plurality of integrated circuit chips and the carrier, wherein the dielectric layer is free of epoxy mold compound;
a redistribution layer (RDL) contacting the dielectric layer and the plurality of connectors, the RDL including a plurality of fan-out vias extending from the plurality of connectors and at least one connector coupling adjacent integrated circuit chips in the plurality of integrated circuit chips; and
a set of solder balls contacting the RDL and connected with the plurality of fan-out vias.

2. (canceled)

3. (canceled)

4. The IC package according to claim 1, wherein the RDL includes at least one of polyimide (PI), polybenzoxazole (PBO), benzocyclobutene (BCB), phenolic resin, olefin or an epoxy molding compound.

5. The IC package according to claim 1, wherein the at least one connector contacts a surface of each of the integrated circuit chips opposite the thermally conductive material.

6. The IC package according to claim 1, wherein the plurality of connectors include a set of copper pillars or vias.

7. (canceled)

8. The IC package according to claim 1, wherein the dielectric layer has a thickness measured from an upper surface of the carrier, the dielectric layer thickness being approximately equal to a height of each of the plurality of connectors as measured from an upper surface of a corresponding one of the plurality of integrated circuit chips.

9. (canceled)

10. The IC package according to claim 1, wherein the thermally conductive material includes solder or a thermally conductive gel.

11. The IC package according to claim 1, further comprising a ground contact contacting the carrier.

12. An integrated circuit (IC) package comprising:
a carrier having a recess, wherein the carrier includes copper or aluminum and includes a base and sidewalls formed as a single piece of material;
a plurality of integrated circuit chips coupled with the carrier inside the recess, the plurality of integrated circuit chips each including a plurality of connectors;
a thermally conductive material between the plurality of integrated circuit chips and the carrier within the recess, the thermally conductive material coupling the plurality of integrated circuit chips with the carrier;
a dielectric layer contacting the plurality of integrated circuit chips and the carrier, the dielectric layer having a thickness measured from an upper surface of the carrier, the dielectric layer thickness being approximately equal to a height of each of the plurality of connectors as measured from an upper surface of a corresponding one of the plurality of integrated circuit chips, wherein the dielectric layer is free of epoxy mold compound;
a redistribution layer (RDL) contacting the dielectric layer and the plurality of connectors, the RDL including a plurality of fan-out vias extending from the plurality of connectors and at least one connector coupling adjacent integrated circuit chips in the plurality of integrated circuit chips; and
a set of solder balls contacting the RDL and connected with the fan-out vias.

13. (canceled)

14. The IC package according to claim 12, wherein the RDL includes at least one of polyamide (PI), polybenzoxazole (PBO), benzocyclobutene (BCB), or an epoxy molding compound.

15. The IC package according to claim 12, wherein the at least one connector contacts a surface of each of the integrated circuit chips opposite the thermally conductive material.

16. The IC package according to claim 12, wherein the plurality of connectors include a set of copper pillars or copper vias.

17. (canceled)

18. (canceled)

19. The IC package according to claim 12, wherein the thermally conductive material includes solder or a thermally conductive gel.

20. The IC package according to claim 1, further comprising a ground contact contacting the carrier.

21. The IC package of claim 1, wherein the dielectric material fills any gaps between plurality of integrated circuit chips within the recess in the carrier.

22. The IC package of claim 12, wherein the dielectric material fills any gaps between plurality of integrated circuit chips within the recess in the carrier.

23. The IC package of claim 1, wherein the carrier includes a base and sidewalls formed as a single piece of material.
